(19) United States
(12) Patent Application Publication
(10) Pub. No.: US 2012/0325512 A1
(43) Pub. Date: Dec. 27, 2012

(54) Weather resistant electrical disconnect junction box

(76) Inventors: David Namey, JR., Pittsburgh, PA (US); Patrick Keenan, (US)

(21) Appl. No.: 13/136,776

(22) Filed: Aug. 10, 2011

Related U.S. Application Data
(60) Provisional application No. 61/571,106, filed on Jun. 21, 2011.

(51) Int. Cl. H05K 5/06

(52) U.S. Cl. 174/50.51

(57) ABSTRACT

A weather resistant electrical disconnect junction box having a base member of molded insulating material with a back panel and side panels forming an internal volume with a front access opening and a cover member of molded insulating material dimensioned and contoured to removably cover the access opening with a weather resistant seal. Internal insulating terminal mounts are integrally molded with the back panel of the box and dimensioned and arranged for selectively receiving and retaining conductive terminal blocks, fuse clips and disconnect terminals in cooperative arrangement for thereby selectively providing a weather resistant fused or non-fused electrical disconnect junction box which permits easy manufacture and assembly.

### CROSS REFERENCE

This application is based upon U.S. Provisional Application No. 61/571,106, filed Jun. 21, 2011, for AC DISCONNECT JUNCTION BOX, the contents of which are incorporated herein by reference in their entirety.

### BACKGROUND OF THE INVENTION

Air conditioning disconnect junction boxes are commonly placed on the outside of a building structure next to an air conditioning condenser unit to provide a disconnect box for terminating power to outdoor air conditioning units during installation or repair. These disconnect boxes are manufactured of metal, and plastic insulating terminal mounts are secured with fasteners to the inside metal back of the junction box and thereafter conductor terminal blocks, fuse clips and disconnect terminals are mechanically secured to the respective insulating terminal mounts.

These conventional AC disconnect junction boxes are problematic in that, particularly in warmer and more humid climates, they readily rust and corrode and they are not conducive to providing a good weather resistant seal to reduce internal corrosion on the electrical contacts.

It is an object of the present invention to provide a weather resistant electrical disconnect junction box which will not rust or corrode and which requires considerably less labor to manufacture and assemble.

### SUMMARY OF THE INVENTION

The weather resistant electrical disconnect junction box of the present invention includes a base member of molded insulating material having a back panel and side panels forming an internal volume with a front access opening, and a cover member of molded material dimensioned and contoured to removably cover the access opening with a weather resistant seal.

Internal insulating terminal mounts are integrally molded with the back panel of the box or base member and dimensioned and arranged for selectively receiving and retaining conductive terminal blocks, fuse clips and disconnect terminals in cooperative arrangement for thereby selectively providing a weather resistant fused or non-fused electrical disconnect junction box.

The junction box of the present invention is thus ready to be completed either as a non-fuse electrical disconnect junction box by including two conductive terminal blocks with stab clips and a ground connection lug secured to the appropriate internally molded terminal mounts, or as a fused version by additionally including two conductive fuse clips with stab clips, and two conductive terminal blocks with fuse clips and transfer plates.

The base member of the box is provided with wire access apertures for permitting access into the box of electrical wires. Fitted snap-in aperture plugs are provided for closing off selective of the apertures. The apertures are generally of two different predetermined diameters commonly used in the industry.

The cover member is typically hinged to the base member and designed to prevent the access of precipitation in the form of rain or snow into the box.

The insulating material utilized for molding the base member and the cover member is preferably selected as a weatherable thermoplastic resin able to withstand extreme hot and cold temperatures, as well as abuse from nature and mankind.

### BRIEF DESCRIPTION OF THE DRAWINGS

Other objects and advantages appear hereinafter in the following description and claims. The accompanying drawings show, for the purpose of exemplification, without limiting the scope of the invention or appended claims, certain practical embodiments of the present invention wherein:

FIG. 1 is a perspective view of the weather resistant electrical disconnect junction box of the present invention illustrated in a closed condition;

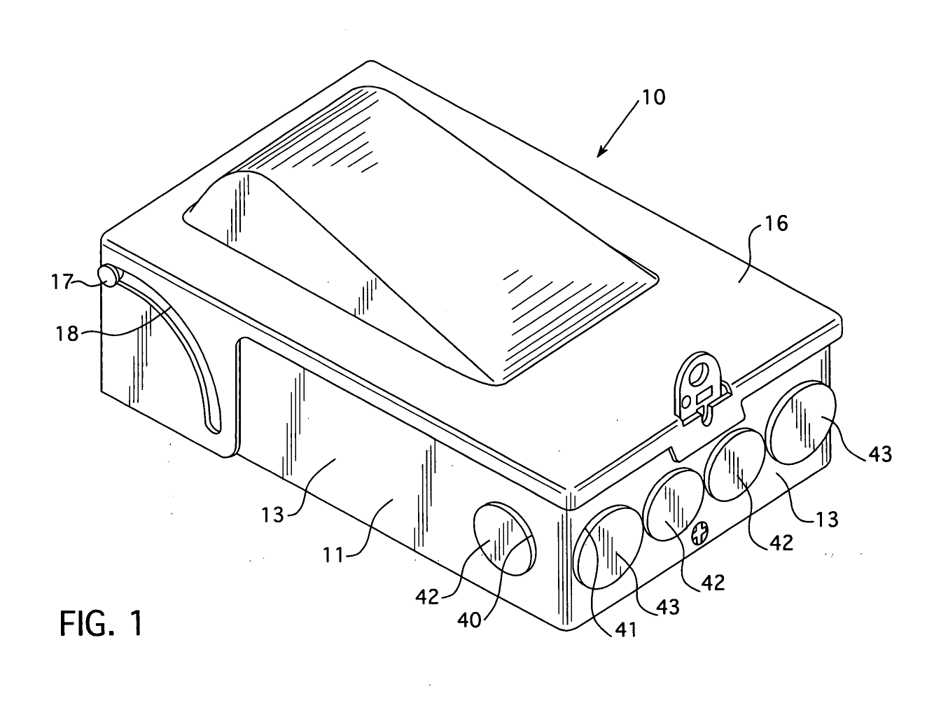

FIG. 2 is a vertical right side view of the junction box shown in FIG. 2 with the cover member shown in an open condition;

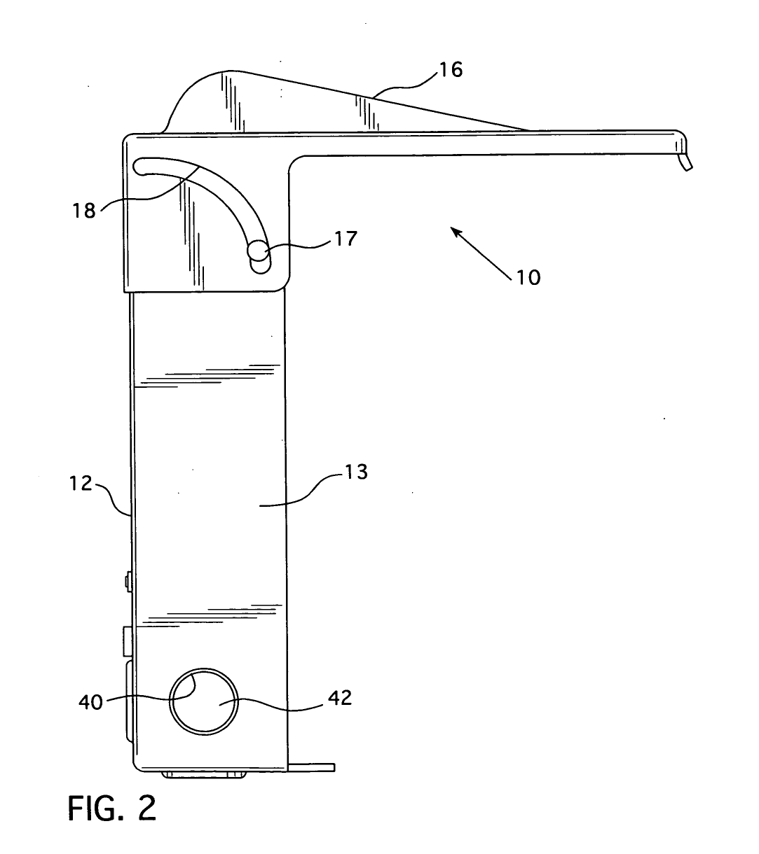

FIG. 3 is a back vertical view of the junction box shown in FIG. 2 with the cover member open;

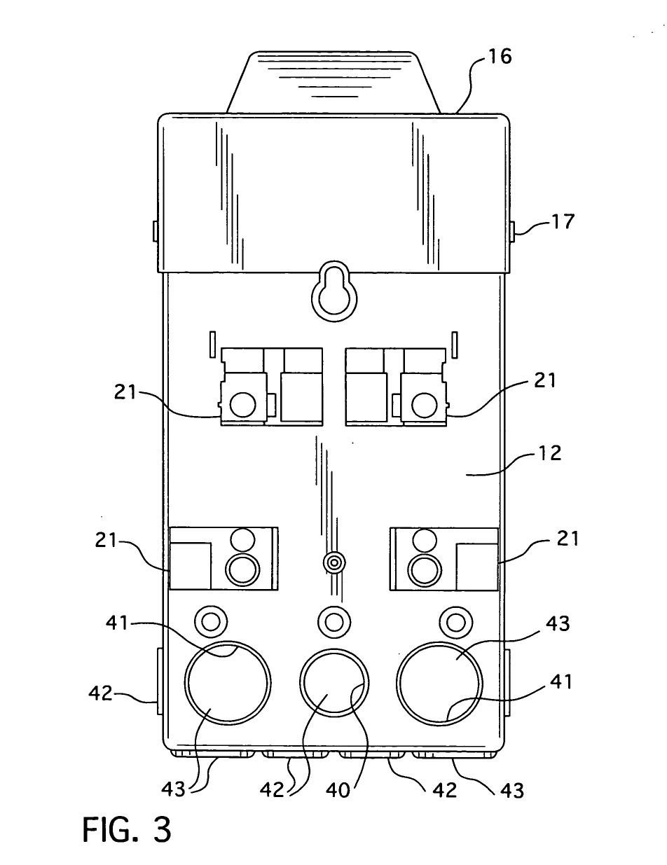

FIG. 4 further illustrates the interior of the box shown in FIG. 3 in perspective;

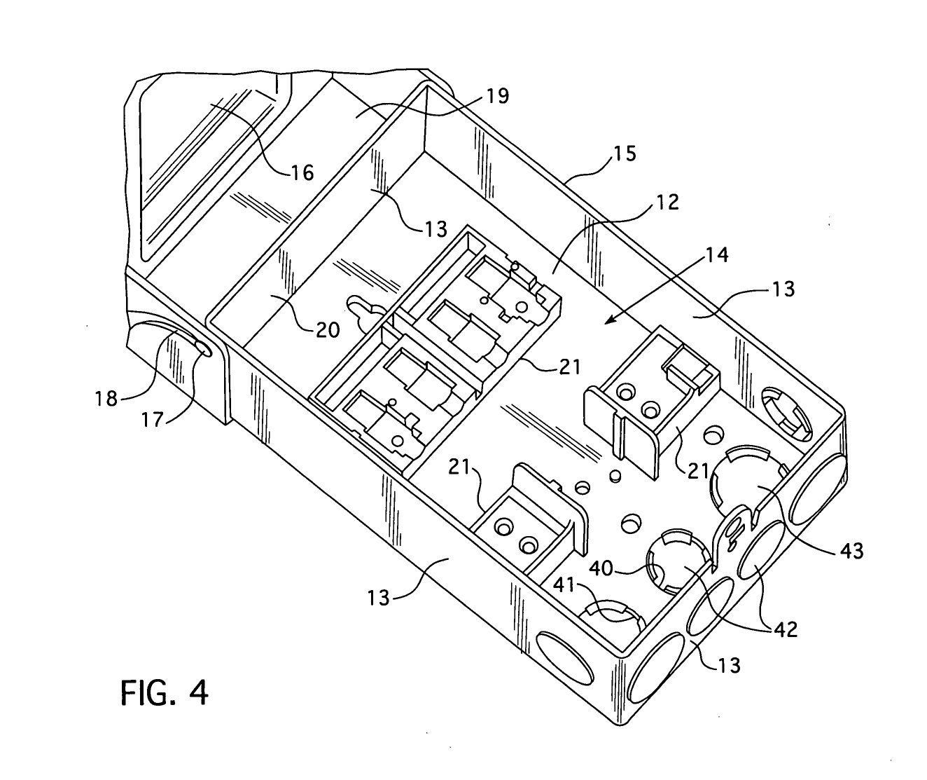

FIG. 5 is another perspective view illustrating the interior of the junction box of the present invention with some of the conductive terminal blocks, fuse clips, disconnect terminals and the ground connection lug removed, and also with two of the wireless access aperture plugs removed;

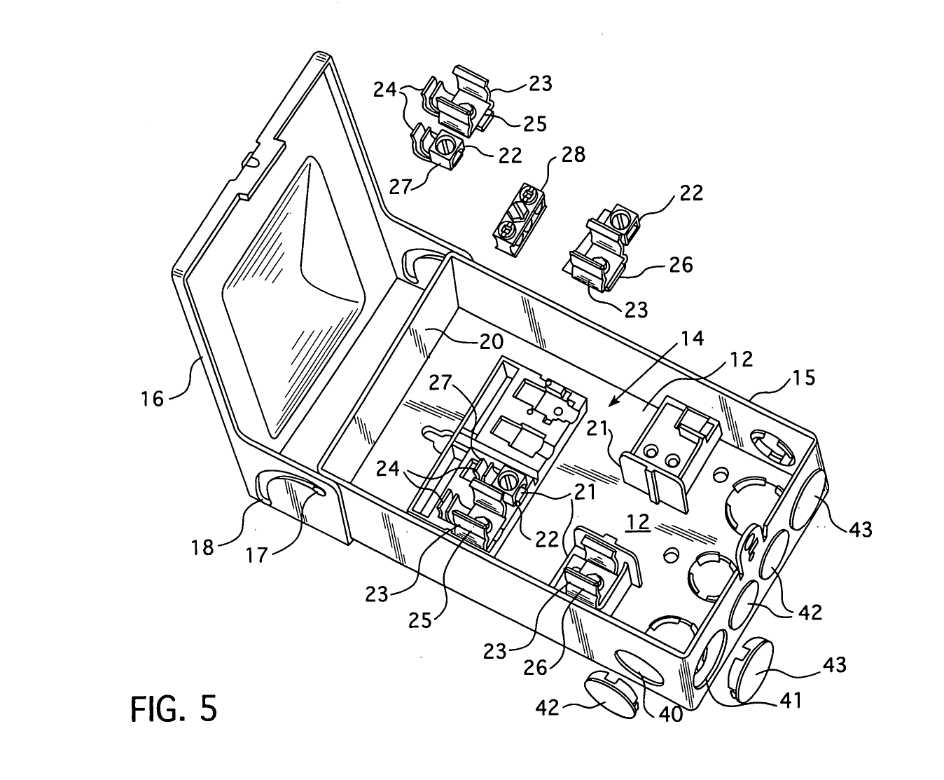

FIG. 6 is a view in front elevation of the junction box of the present invention showing all conductive terminal blocks, stab clips, the ground connection lug, two conductive fuse clips with stab clips and two conductive terminals with fuse clips and transfer plates thereby illustrating the junction box as assembled to provide a fused version thereof; and

FIG. 7 is a perspective view of the junction box shown in FIG. 6.

### DETAILED DESCRIPTION OF A PREFERRED EMBODIMENT

Referring to the drawings, the weather resistant electrical disconnect junction box 10 of the present invention includes a base member 11 of molded insulating material, such as a weatherable thermoplastic resin, having a back panel 12 and four side panels 13 forming an internal volume 14 with a front access opening 15.

Cover member 16 is also molded of insulating material, such as a thermoplastic resin, and it is dimensioned and contoured to removably cover the access opening 15 with a weather resistant seal. In this regard, note that the cover member 16 is hinged at 17 to base member 11 and is provided with a slotted hinge connection 18 so that the upper cover 19 of cover member 16 encases the upper end 20 of base member 13 when closed to prevent access of rain water and snow into the interior 14.

Internal insulating terminal mounts 21 are integrally molded with the back panel 12 of base member 11 and are dimensioned and arranged for selectively receiving and retaining conductive terminal block 22, conductive fuse clips 23 and disconnect terminals 24, in cooperative arrangement as illustrated for thereby selectively providing a weather resistant fused or non-fused electrical disconnect junction box 10.

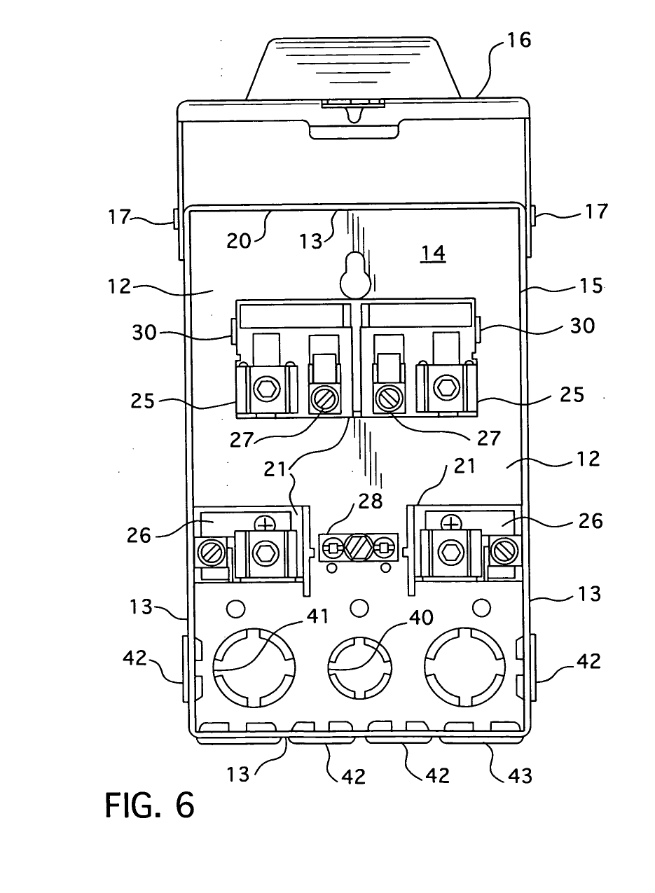

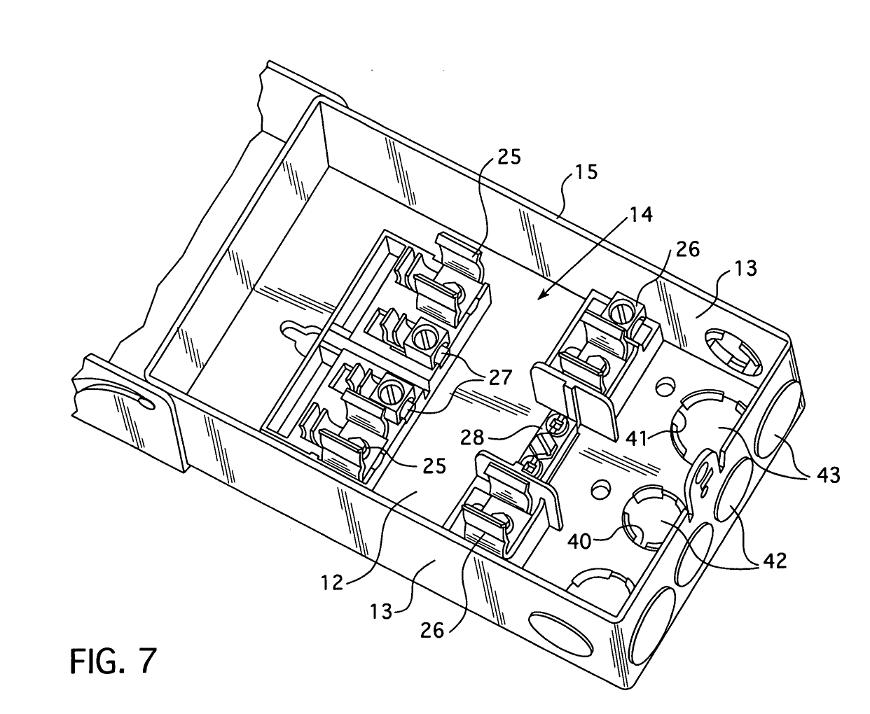

The junction box illustrated in FIGS. 6 and 7 are illustrated in the full fused version with the conductive fuse clips with stab clip combinations 25 and the two conductive terminal blocks with fuse clips and transfer plate combinations 26 in place, together with the two conductive terminal blocks with stab clip combinations 27 and with the ground connection lug 28.

To provide the non-fused version, fuse clip combinations 26 and 25 are not installed.

The internal insulating terminal mounts 21, being integrally molded with back panel 12, do not have to be separately manufactured and separately installed as required in the prior art, and all the internal conductive hardware is quickly mounted to the respective terminal mounts 21, either by conventional mechanical screw connections as illustrated or by snap-in fittings (not shown).

The junction box of the present invention is thus illustrated ready for use. Additional elements (not shown and already available as off the shelf items) will be added to the fused or non-fused version of the box of the present invention when put in use, such as a cover base which will be snap fitted to snap prongs 30 to cover the electrical stab clip connections 24 and provide a mounting base for a plug-in disconnect stab blade and an insulating plastic terminal cover to cover up the fuse clips 23 which are retaining fuses therein.

The back panel 12 and selected side panels 13 of the base member 11 are provided with wire access apertures 40 and 41 therein of two different predetermined diameters (typically ½ inch and ¾ inch) to provide access as desired for insulated wires for connection to the interior terminals in the box. Apertures 40 and 41 which are not in use, are closed off with aperture plugs 42 and 43 respectively, which have flexible feet for snapping into the respective apertures to retain the plugs therein.

I claim:

1. A weather resistant electrical disconnect junction box, comprising:
a base member of molded insulating material having a back panel and side panels forming an internal volume with a front access opening;
a cover member of molded insulating material dimensioned and contoured to removably cover said access opening with a weather resistant seal;
internal insulating terminal mounts integrally molded with said back panel and dimensioned and arranged for selectively receiving and retaining conductive terminal blocks, fuse clips and disconnect terminals in cooperative arrangement for thereby selectively providing a weather resistant fused or non-fused electrical disconnect junction box.

2. The junction box of claim 1, including two conductive terminal blocks with stab clips and a ground connection lug.

3. The junction box of claim 2, including two conductive fuse clips with stab clips and two conductive terminal blocks with fuse clips and transfer plates.

4. The junction box of claim 1, said base member having wire access apertures therein and removable aperture plugs closing off selected of said apertures.

5. The junction box of claim 4, wherein said apertures are of two different predetermined diameters.

6. The junction box of claim 1, wherein said cover member is hinged to said base member.

7. The junction box of claim 1, wherein said insulating material is a thermoplastic resin.
